(19) United States
(12) Patent Application Publication
(10) Pub. No.: US 2013/0088832 A1
(43) Pub. Date: Apr. 11, 2013

(54) THERMAL PROTECTION CIRCUIT AND ELECTRONIC DEVICE

(71) Applicants: JI-CHAO LI, Shenzhen (CN); BO DENG, Shenzhen (CN)

(72) Inventors: JI-CHAO LI, Shenzhen (CN); BO DENG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/448,400

(22) Filed: Apr. 17, 2012

(30) Foreign Application Priority Data
Oct. 6, 2011 (CN) 201110292897.6

(51) Int. Cl. H05K 7/20; H02H 5/04

(52) U.S. Cl. 361/679.48; 361/103

(57) ABSTRACT

A thermal protection circuit includes a temperature detecting circuit, a comparing circuit, and a switching circuit. The temperature detecting circuit senses an internal temperature of the electronic device and outputs a voltage signal decreasing proportionally with the internal temperature of the electronic device increasing. The comparing circuit compares the voltage signal to a high voltage threshold or a low voltage threshold, thereby outputting a corresponding driving signal. The switching circuit turns on/off under the control of the driving signal.

### BACKGROUND

1. Technical Field

The disclosure generally relates to electronic devices, and particularly to a thermal protection circuit and an electronic device using the thermal protection circuit.

2. Description of the Related Art

A plurality of integrated circuits and chips are employed in an electronic device to satisfy multiple requirements. When the electronic device has been operating for an exceedingly long time, the integrated circuits and chips generate a great deal of heat. Much of the generated heat cannot be dissipated in real-time and may cause irreversible damage to the electronic device.

Therefore, there is room for improvement within the art.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views. Wherever possible, the same reference numbers are used throughout the drawings to refer to the same or like elements of an embodiment.

FIG. 1 is a block diagram of an electronic device, according to an exemplary embodiment.

FIG. 2 is a circuit diagram of one embodiment of the electronic device shown in FIG. 1 of the disclosure.

FIG. 3 is a diagram showing a performance of a first comparator of the electronic device shown in FIG. 2.

### DETAILED DESCRIPTION

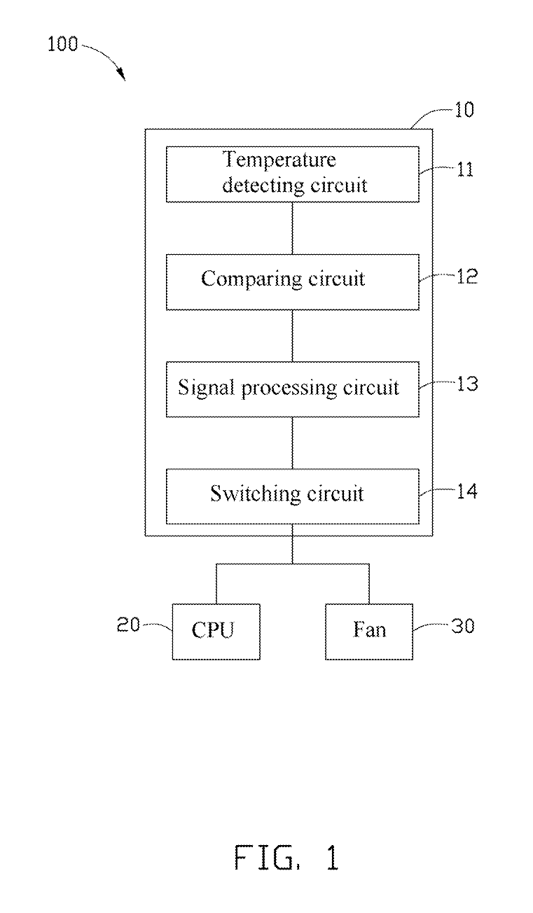

FIG. 1 is a block diagram of an electronic device, according to an exemplary embodiment. The electronic device 100 includes a thermal protection circuit 10, a central processing unit (CPU) 20, and a fan 30. The protection circuit 10 is connected to both the CPU 20 and the fan 30, and prevents the electronic device 100 from over-heating. In detail, when an internal temperature of the electronic device 100 exceeds a predetermined upper temperature, such as 60° C., the thermal protection circuit 10 drives the CPU 20 to slow a operating frequency of the CPU 20, and increases a rotational speed of the fan 30, thereby lowering internal temperature of the electronic device 100. Once the electronic device 100 cools down to a predetermined lower temperature, such as 25° C., the thermal protection circuit 10 drives the CPU 20 and the fan 30 to work normally, i.e., the CPU 20 recovers to a normally operating frequency, and the fan 30 recovers to a normally rotational speed.

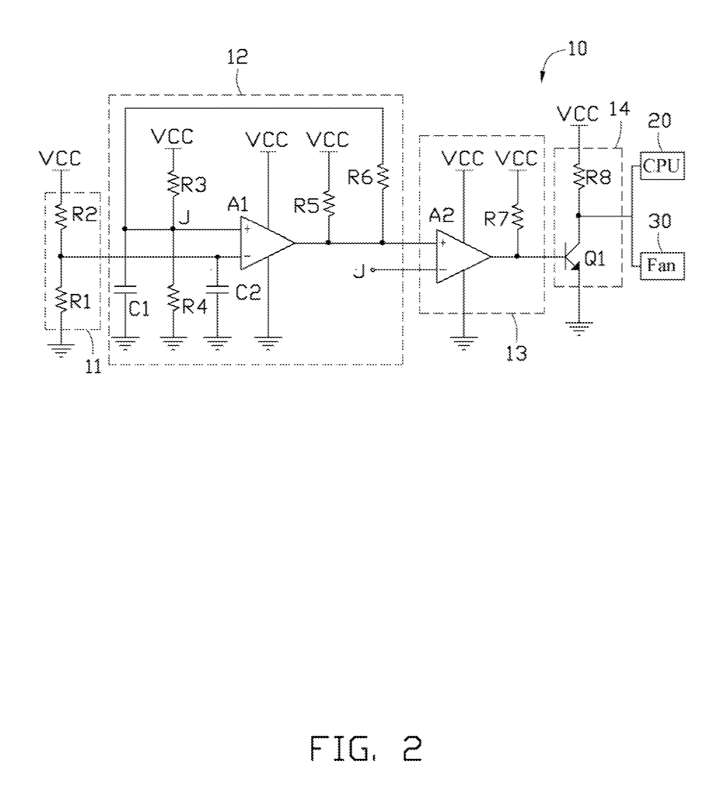

Also referring to FIG. 2, the thermal protection circuit 10 includes a temperature detecting circuit 11, a comparing circuit 12, a signal processing circuit 13, and a switching circuit 14. The temperature detecting circuit 11 sensors the internal temperature of the electronic device 100, and outputs a voltage signal in accordance with the internal temperature. In detail, the temperature detecting circuit 11 includes a first resistor R1, and a second resistor R2. The first resistor R1 is a thermal resistor. The second resistor R2 and the first resistor R1 are connected in turn between a power supply VCC and the ground. A common node of the first resistor R1 and the second resistor R2 is defined as an output of the temperature detecting circuit 11 to output the voltage signal.

In the present embodiment, the first resistor R1 is a negative temperature coefficient (NTC) resistor, and has a resistance that is inversely proportional to the internal temperature of the electronic device 100. Therefore, the temperature detecting circuit 11 outputs the voltage signal decreasing proportionally with the internal temperature of the electronic device 100 increasing.

The comparing circuit 12 can be a hysteresis comparing circuit, and includes a first comparator A1. The first comparator A1 can be a LM393 comparator. A negative input of the first comparator A1 is connected to the output of the temperature detecting circuit 11 (i.e., the common node of the first resistor R1 and the second resistor R2). A positive input of the first comparator A1 is connected to the power supply VCC through a third resistor R3, and also connected to ground through a forth resistor R4. An output of the first comparator A1 is connected to the power supply VCC via a fifth resistor R5. The output of the first comparator A1 is also connected to a common node J of the positive input of the comparator A1, the third resistor R3 and the fourth resistor R4 through a sixth resistor R6.

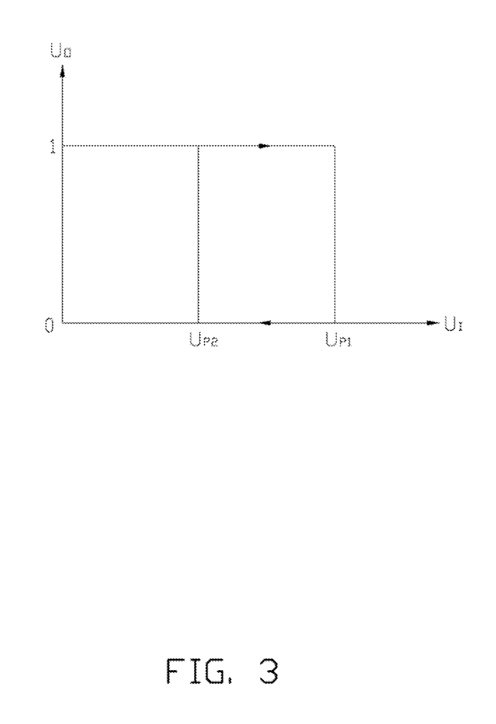

Referring to FIG. 3, the comparing circuit 12 compares the voltage signal of the internal temperature to a high voltage threshold and a low voltage threshold. The high voltage threshold represents the lower temperature value of the electronic device 100. The low voltage threshold represents the upper temperature value of the electronic device 10. In addition, according to a performance of the comparing circuit 12, the comparing circuit 12 has a high triggering voltage U_{P1}, and a low triggering voltage Up lower than the high triggering voltage U_{P1}. When a voltage of the negative input of the first comparator A1 (i.e., the parameter U_{I}) is greater than the high triggering voltage U_{P1}, the output of the first comparator A1 outputs a low level (e.g., logic 0). In other embodiments, when the voltage of the negative input of the first comparator A1 is lower than the high triggering voltage U_{P1}, the output of the first comparator A1 is high-impedance, and disconnected with the fifth resistor R5. In this way, a common node of the fifth resistor R5 and the sixth resistor R6 is defined as an output of the comparing circuit 12 (i.e., the parameter Uo) to output a high level (e.g., logic 1). When the output of the first comparator A1 is high-impedance, the voltage of the output of the comparing circuit 12 is greater than the voltage of the positive input of the first comparator A1.

Therefore, by setting the high triggering voltage U_{P1} and the low triggering voltage U_{P2} respectively equal to the high voltage threshold and the low voltage threshold, the comparing circuit 12 compares the voltage signal to the predetermined thresholds (i.e., the high triggering voltage U_{P1} and the low triggering voltage U_{P2}), thereby comparing the internal temperature of the electronic device 100 to the lower temperature value and the upper temperature value to output a first driving signal (e.g., a signal of logic 1) or a second driving signal (e.g., a signal of logic 0) to the anti-interference 13. For example, when the internal temperature of the electronic device 100 exceeds the upper temperature value (i.e., the output voltage of the temperature detecting circuit 11 is below to the low triggering voltage U_{P2}), the output of the first comparator A1 is high-impedance. Accordingly the comparing circuit 12 outputs the first driving signal. In other embodiments, when the internal temperature of the electronic device 100 is below to the lower temperature value (i.e., the output voltage of the temperature detecting circuit 11 is greater than the high triggering voltage U_{P1}), the comparing circuit 12 outputs the second driving signal.

The signal processing circuit 13 is connected between the comparing circuit 12 and the switching circuit 14. It should be understood that direct and continuous output of the first and second driving signals by the comparing circuit 12 to the switching circuit 14, which will correspondingly lead to constant switching on/off of the switching circuit 14, which may damage the switching circuit 14. Thus, the signal processing circuit 13 receives and processes the first driving signal or the second driving voltage to output a steady first driving voltage (e.g., logic 1) or a steady second driving voltage (e.g., logic 0) to the switching circuit 14, thereby preventing the switching circuit 14 from damage due to turning on/off constantly.

In detail, the signal processing circuit 13 includes a second comparator A2. The second comparator can be a LM393 comparator. A positive input of the second comparator A2 is connected to the output of the comparing circuit 12 (i.e., the common node of the fourth resistor R5 and the fifth resistor R6). A negative input of the second comparator A2 is connected to the common node J (i.e., the positive input of the first comparator A1). An output of the second comparator A2 is connected to the power supply VCC through a seventh resistor R7, and also connected to the switching circuit 14.

When the comparing circuit 12 outputs the first driving signal, the first driving signal is transmitted to the positive input of the second comparator A2, and the negative input of the second comparator A2 receives a voltage lower than the voltage of the output of comparing circuit 12 from the positive input of the first comparator A1. In this way, the output of the second comparator A2 is high-impedance, which leads to the disconnection between the output of the second comparator A2 and the seventh resistor R7, thereby causing the power supply VCC to output the first driving voltage (e.g., logic 1) to the switching unit 14 through the seventh resistor R7. In other embodiments, when the comparing circuit 12 outputs the second driving signal, the second driving signal is transmitted to the positive input of the second comparator A2. Since the negative input of the second comparator A2 is connected to the positive input of the first comparator A1, thus the negative input of the second comparator A2 receives a voltage from the positive input of the first comparator A1. In this way, according to a performance of the second comparator A2, the second comparator A2 outputs the second driving voltage (e.g., logic 0) to the switching circuit 14.

The switching unit 14 includes a bipolar junction transistor (BJT) Q1, and a eighth resistor R8. A base of the BJT Q1 is connected to the output of the signal processing circuit 13. An emitter of the BJT Q1 is connected to ground. A collector of the BJT Q1 is connected to the power supply VCC through the eighth resistor R8, and also connected to both the CPU 20 and the fan 30.

After receiving the first driving voltage or the second driving voltage from the signal processing circuit 13, the switching circuit 14 turns on or off, thereby controlling an operation of the CPU 20 and the fan 30. For example, when the internal temperature of the electronic device 100 exceeds the upper temperature value, such as 60° C., the switching circuit 14 receives the first driving voltage, and the BJT Q1 turns on. Then both the CPU 20 and the fan 30 are connected to ground through the BJT Q1 to obtain a low level (e.g., logic 0). Upon receiving the low level, the CPU 20 will slowdown, and the rotational speed of the fan 30 increases, thereby cooling down the internal temperature of the electronic device 100.

Alternatively, when the internal temperature of the electronic device 100 is less than the lower temperature value, such as 25° C., the switching circuit 14 receives the second driving voltage, and the BJT Q1 turns off. Then both the CPU 20 and the fan 30 are connected to the power supply VCC through the eighth resistor R8 to obtain a high level. Upon receiving the high level, the CPU 20 and the fan 30 would recover to normal operation.

In the present embodiment, when the internal temperature of the device 100 is below the upper temperature value, such as 60° C., the temperature detecting circuit 11 outputs the voltage signal not lower than the low triggering voltage U_{P2}. In this way, the comparing circuit 12 outputs the second driving signal. Since the positive input of the second comparator A2 is connected to the output of the comparing circuit 12, so the positive input of the second comparator A2 receives a voltage less than the voltage of the negative input of the second comparator A2. Therefore, according to the characters of the second comparator A2, the second comparator A2 outputs the second driving voltage. Then the BJT Q1 receives the second driving voltage, and turns off. Obviously, both the CPU 20 and the fan 30 would connect to the power supply VCC through the eighth resistor R8 to obtain a high level, and respectively work normally.

When the internal temperature of the electronic device 100 exceeds the upper temperature value, the temperature detecting circuit 11 outputs the voltage signal lower than the low triggering voltage U_{P2}. According to the performance of the comparing circuit 12, the first comparator A1 outputs a high impedance. Accordingly, the output of the first comparator A1 is disconnected from the fourth resistor R5. In this way, the output of the comparing circuit 12 outputs a voltage greater than the voltage of negative input of the second comparator A2. Therefore, the signal processing circuit 13 outputs the first driving voltage, and the BJT Q1 turns on. Obviously, both the CPU 20 and the fan 30 would connect to ground through the BJT Q1 to obtain a low level (e.g., logic 0). Upon receiving the low level, the CPU 20 will slow down, and the rotational speed of the fan 30 increases, thereby cooling down the internal temperature of the electronic device 100.

As the electronic device 100 cools down, the internal temperature falls and the voltage signal of the internal temperature rises proportionally. When the internal temperature of the electronic device 100 falls to below the lower temperature value, the voltage signal of the internal temperature signal rises to above the high triggering voltage U_{P1}. Then the comparing circuit 12 outputs the second driving signal again. Accordingly, the signal processing circuit 13 outputs the second driving voltage, and the BJT Q1 turns off. Therefore, both the CPU 20 and the fan 30 obtain a high level again, and recover to work normally.

In the other alternative embodiments, the first resistor R1 is a positive temperature coefficient (PTC) resistor, and has a resistance directly proportional to the internal temperature of the electronic device 100 increasing. In detail, the first resistor R1 and the second resistor R2 are connected in turn between the power supply VCC and the ground. Thus, the temperature detecting circuit 11 also outputs the voltage signal decreasing proportionally with the internal temperature of the electronic device 100 increasing.

In the other alternative embodiments, the positive input and the negative input of the first comparator A1 are respectively connected to ground through capacitors C1, C2 for filtering the voltages of the positive input and the negative input of the first comparator A1.

In the present specification and claims, the word “a” or “an” preceding an element does not exclude the presence of a plurality of such elements. Further, the word “comprising” does not exclude the presence of elements or steps other than those listed.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of this exemplary disclosure to the full extent indicated by the broad general meaning of the terms in which the appended claims are expressed.

What is claimed is:

1. A thermal protection circuit for an electronic device, comprising:
a temperature detecting circuit sensing an internal temperature of the electronic device and outputting a voltage signal that decreases proportionally as the internal temperature of the electronic device increases;
a comparing circuit connected to the temperature detecting circuit, the comparing circuit comparing the voltage signal to a high voltage threshold of the electronic device or a low voltage threshold of the electronic device, and outputting a corresponding first driving signal or a second driving signal; and
a switching circuit connected to the comparing circuit, wherein the switching circuit turns on when the comparing circuit outputs the first driving signal, and turns off when the comparing circuit outputs the second driving signal.

2. The thermal protection circuit as claimed in claim 1, wherein the temperature detecting circuit includes a first resistor and a second resistor connected in series between a power supply and ground, a common node of the first resistor and the second resistor is defined as an output of the temperature detecting circuit to output the voltage signal.

3. The thermal protection circuit as claimed in claim 2, wherein first resistor is a negative temperature coefficient resistor, and the second resistor and the first resistor are connected in turn between the power supply and ground.

4. The thermal protection circuit as claimed in claim 2, wherein the first resistor is a positive temperature coefficient resistor, and the first resistor and the second resistor are connected in turn between the power supply and ground.

5. The thermal protection circuit as claimed in claim 2, wherein the comparing circuit includes a first comparator, a negative input of the first comparator is connected to the output of the temperature detecting circuit, a positive input of the first comparator is connected to the power supply through a third resistor, and connected to ground via a fourth resistor, an output of the first comparator is connected to the power supply through a fifth resistor, and also connected to a common node of the positive input of the first comparator, the third resistor, and the fourth resistor through a sixth resistor, a common node of the fifth resistor and the sixth resistor is defined as an output of the comparing circuit to output the first driving signal or the second driving signal.

6. The thermal protection circuit as claimed in claim 5, wherein the first comparator has a high triggering voltage and a low triggering voltage respectively equal to the high voltage threshold value and the low voltage threshold value, when the voltage signal is greater than the high triggering voltage, the comparing circuit outputs the second driving signal, when voltage signal is lower than the low triggering voltage, the comparing circuit outputs the first driving signal.

7. The thermal protection circuit as claimed in claim 5, further comprising a signal processing circuit connected between the comparing circuit and the switching circuit, receiving the first driving signal or the second driving voltage, and outputting a steady first driving voltage or a steady second driving voltage to the switching circuit.

8. The thermal protection circuit as claimed in claim 7, wherein the signal processing circuit includes a second comparator, a positive input of the second comparator is connected to the output of the comparing circuit, a negative input of the second comparator is connected to the positive input of the first comparator, an output of the second comparator is connected to the power supply through a seventh resistor, and also connected to the switching circuit.

9. The thermal protection circuit as claimed in claim 8, wherein the switching circuit includes a bipolar junction transistor (BJT) and a eighth resistor, a base of the BJT is connected to the output of the second comparator, an emitter of the BJT is connected to ground, a collector of the BJT is connected to the power supply through the eighth resistor, the BJT turns on with the internal temperature of the electronic device greater than the upper temperature, and turns off with the internal temperature of the electronic device less than the lower temperature.

10. An electronic device, comprising:
a central processing unit (CPU);
a fan; and
a thermal protection circuit connected to both the CPU and the fan, the thermal protection circuit comprising:
a temperature detecting circuit sensing an internal temperature of the electronic device and outputting a voltage signal that decreases proportionally as the internal temperature of the electronic device increases;
a comparing circuit connected to the temperature detecting circuit, the comparing circuit comparing the voltage signal to a high voltage threshold of the electronic device or a low voltage threshold of the electronic device respectively, thereby outputting a corresponding first driving signal or a second driving signal; and
a switching circuit connected to the comparing circuit, wherein when the comparing circuit outputs the first driving signal, the switching circuit turns on, the CPU would slowdown, and the rotational speed of the fan increases, thereby cooling down the internal temperature of the electronic device; when the comparing circuit outputs the second driving signal, the switching circuit turns off, the CPU and the fan recover to work normally.

11. The electronic device as claimed in claim 10, wherein the temperature detecting circuit includes a first resistor and a second resistor connected in series between a power supply and ground, a common node of the first resistor and the second resistor is defined as an output of the temperature detecting circuit to output the voltage signal.

12. The electronic device as claimed in claim 11, wherein first resistor is a negative temperature coefficient resistor, and the second resistor and the first resistor are connected in turn between the power supply and ground.

13. The electronic device as claimed in claim 11, wherein the first resistor is a positive temperature coefficient resistor, and the first resistor and the second resistor are connected in turn between the power supply and ground.

14. The electronic device as claimed in claim 11, wherein the comparing circuit includes a first comparator, a negative input of the first comparator is connected to the output of the temperature detecting circuit, a positive input of the first comparator is connected to the power supply through a third resistor, and connected to ground via a fourth resistor, an output of the first comparator is connected to the power supply through a fifth resistor, and also connected to a common node of the positive input of the first comparator, the third resistor, and the fourth resistor through a sixth resistor, a common node of the fifth resistor and the sixth resistor is defined as an output of the comparing circuit to output the first driving signal or the second driving signal.

15. The electronic device as claimed in claim 14, wherein the first comparator has a high triggering voltage and a low triggering voltage respectively equal to the high voltage threshold value and the low voltage threshold value, when the voltage signal is greater than the high triggering voltage, the comparing circuit outputs the second driving signal, when voltage signal is lower than the high triggering voltage, the comparing circuit outputs the first driving signal.

16. The electronic device as claimed in claim 14, further comprising a signal processing circuit connected between the comparing circuit and the switching circuit, receiving the first driving signal or the second driving voltage, and outputting a steady first driving voltage or a steady second driving voltage to the switching circuit.

17. The electronic device as claimed in claim 16, wherein the signal processing circuit includes a second comparator, a positive input of the second comparator is connected to the output of the comparing circuit, a negative input of the second comparator is connected to the positive input of the first comparator, an output of the second comparator is connected to the power supply through a seventh resistor, and also connected to the switching circuit.

18. The electronic device as claimed in claim 17, wherein the switching circuit includes a BJT and a eighth resistor, a base of the BJT is connected to the output of the second comparator, an emitter of the BJT is connected to ground, a collector of the BJT is connected to the power supply through the eighth resistor, the BJT turns on with the internal temperature of the electronic device greater than the upper temperature, and turns off with the internal temperature of the electronic device less than the lower temperature.

19. A thermal protection circuit applying to an electronic device, comprising:
a temperature detecting circuit sensing an internal temperature of the electronic device and outputting a voltage signal in accordance with the internal temperature of the electronic device;
a comparing circuit connected to the temperature detecting circuit, and comparing the voltage signal to a predetermined threshold of the comparing circuit, thereby outputting a driving signal in accordance with the comparing result; and
a switching circuit connected to the comparing circuit, wherein the switching circuit turns on/off under the control of the driving signal.
